(19) United States
(12) Patent Application Publication
(10) Pub. No.: US 2024/0412986 A1
(43) Pub. Date: Dec. 12, 2024

(54) SUBSTRATE PROCESSING APPARATUS AND SUBSTRATE PROCESSING METHOD

(71) Applicant: SEMES CO., LTD., Cheonan-si (KR)

(72) Inventors: Byung Woo SIM, Yongin-si (KR); Bok Kyu LEE, Cheonan-si (KR)

(73) Assignee: SEMES CO., LTD., Cheonan-si (KR)

(21) Appl. No.: 18/594,391

(22) Filed: Mar. 4, 2024

(30) Foreign Application Priority Data
Jun. 7, 2023 (KR) 10-2023-0072949

(51) Int. Cl. H01L 21/67; B08B 3/02; H01L 21/02; H01L 21/306

(52) U.S. Cl. CPC H01L 21/6708; B08B 3/022; H01L 21/02057; H01L 21/30604; H01L 21/67051

(57) ABSTRACT

Provided are a substrate processing apparatus and a substrate processing method that are capable of maintaining an etch rate of a substrate within a predetermined range by preventing the amount of dissolved oxygen from being concentrated in a specific region of the substrate when a chemical is supplied to a center of the substrate. The apparatus for processing a substrate includes: a chamber having a processing space; a support unit for supporting and rotating a substrate in the processing space; a liquid discharge unit including a nozzle for discharging a treatment liquid onto a substrate supported by the support unit in a liquid phase; and a liquid supply unit for supplying the treatment liquid to the liquid discharge unit, in which, when viewed from above, the nozzle is spaced apart from a center of the substrate such that when the treatment liquid is supplied to the substrate rotated by the support unit, the treatment liquid is not sprayed by the nozzle at a position overlapping the center of the substrate.

### CROSS-REFERENCE TO RELATED APPLICATIONS

This application claims priority to and the benefit of Korean Patent Application No. 10-2023-0072949 filed in the Korean Intellectual Property Office on Jun. 7, 2023 the entire contents of which are incorporated herein by reference.

### TECHNICAL FIELD

The present invention relates to an apparatus for processing a substrate, and more particularly, to a substrate processing apparatus and a substrate processing method which process a substrate.

### BACKGROUND ART

To manufacture semiconductor devices or flat display panels, various processes, such as deposition, photography, etching, and cleaning, are performed. Among these processes, the photography process includes an application process in which a photosensitive liquid, such as a photoresist, is applied to a surface of a substrate to form a film, an exposure process in which a circuit pattern is transferred to the film formed on the substrate, and a development process in which the film formed on the substrate is selectively removed from the exposed region or an opposite region of the exposed region. Further, a heat treatment process is performed before and after the application process, the exposure process, and the development process.

On the other hand, the substrate processing apparatus performing the above cleaning process supplies acidic or alkaline chemicals to the substrate, cleans the supplied chemicals with a rinse solution, and dries the substrate with a drying fluid.

In this case, the chemical contains oxygen components, as well as chemical components, and since too much oxygen components change the etch rate, the amount of dissolved oxygen in the chemical needs be maintained and supplied at a predetermined level.

The chemical that has the amount of dissolved oxygen at the predetermined level is supplied to the center of the rotating substrate and then spreads out to the edge areas as the substrate rotates to clean the substrate.

In this case, the center of the substrate has the higher amount of dissolved oxygen than the other regions of the substrate due to the continuous supply of chemicals, and as a result, the center of the substrate exhibits a greater change in etch rate than the other regions of the substrate.

Accordingly, when the chemical is supplied to the substrate, nitrogen gas is blown and supplied to improve the high mount of dissolved oxygen near the center.

However, when nitrogen gas is supplied along with the chemical, the nitrogen gas may be concentrated in the center of the substrate to cause an increase in the amount of dissolved oxygen in other regions, or may cause turbulence around the surface of the chemical to cause an irregular distribution of dissolved oxygen.

As a result, the chemical causes irregular changes in the amount of dissolved oxygen in the entire region of the substrate due to the above phenomena caused by nitrogen gas, and the substrate is unevenly etched in the entire area.

### SUMMARY OF THE INVENTION

The present invention to solve the foregoing problems provides a substrate processing apparatus and a substrate processing method that are capable of maintaining an etch rate of a substrate within a predetermined range by preventing the amount of dissolved oxygen from being concentrated in a specific region of the substrate when a chemical is supplied to a center of the substrate.

The object of the present invention is not limited thereto, and other objects not mentioned will be clearly understood by those of ordinary skill in the art from the following description.

An exemplary embodiment of the present invention an apparatus for processing a substrate, the apparatus including: a chamber having a processing space; a support unit for supporting and rotating a substrate in the processing space; a liquid discharge unit including a nozzle for discharging a treatment liquid onto a substrate supported by the support unit in a liquid phase; and a liquid supply unit for supplying the treatment liquid to the liquid discharge unit, in which when viewed from above, the nozzle is spaced apart from a center of the substrate such that when the treatment liquid is supplied to the substrate rotated by the support unit, the treatment liquid is not sprayed by the nozzle at a position overlapping the center of the substrate.

According to the exemplary embodiment, the nozzle may be disposed at a predetermined distance apart in an upward direction from a top surface of the substrate to supply the treatment liquid.

According to the exemplary embodiment, the nozzle may supply the treatment liquid in a direction vertical to the top surface of the substrate.

According to the exemplary embodiment, the nozzle may discharge the treatment liquid at a location close to the center of the substrate between a distance to the center of the substrate and a distance to an edge of the substrate.

According to the exemplary embodiment, the treatment liquid supplied to the substrate may be spread to each of a center side of the substrate and to an edge side of the substrate.

According to the exemplary embodiment, when a location from which the treatment liquid is supplied is referred to as a first position, and a center of the distance from the center of the substrate to the edge of the substrate is referred to as a second location, the first position may be located closer to the center of the substrate than the second position.

According to the exemplary embodiment, when the distance from the center of the substrate to the edge of the substrate is referred to as a first distance, the first position may be selected within a range of 5% to 15% of the first distance from the center of the substrate.

According to the exemplary embodiment, the treatment liquid may contain an ammonia component.

According to the exemplary embodiment, organic residues and particles may be formed on the substrate before the treatment liquid is supplied.

According to the exemplary embodiment, the treatment liquid may be formed with the amount of dissolved oxygen of 1500 ppb to 2500 ppb.

According to the exemplary embodiment, the apparatus may further include: a dissolved oxygen amount detection unit that is connected to the liquid discharge unit, and detects the amount of dissolved oxygen of the treatment liquid and calculates dissolved oxygen amount data; and a controller that receives the dissolved oxygen amount data in linkage with the dissolved oxygen amount detection unit, and varies a position at which the treatment liquid is supplied according to the dissolved oxygen amount data.

Another exemplary embodiment of the present invention provides a substrate processing method of processing a substrate, the substrate processing method including: a processing operation of supplying a treatment liquid through a nozzle onto a substrate rotating while being seated on a support unit; and a rinse operation of supplying another treatment liquid through a nozzle onto the substrate rotating while being seated on the support unit to remove the treatment liquid, in which in the processing operation, when viewed from above, the nozzle is spaced apart from a center of the substrate such that when the treatment liquid is supplied to the substrate rotated by the support unit, the treatment liquid is not sprayed at a position overlapping the center of the substrate.

According to the exemplary embodiment, in the processing operation, the nozzle may be disposed at a predetermined distance apart in an upward direction from a top surface of the substrate to supply the treatment liquid.

According to the exemplary embodiment, in the processing operation, the nozzle may supply the treatment liquid in a direction vertical to the top surface of the substrate.

According to the exemplary embodiment, in the processing operation, the nozzle may discharge the treatment liquid at a location close to the center of the substrate between a distance to the center of the substrate and a distance to an edge of the substrate.

According to the exemplary embodiment, in the processing operation, the treatment liquid supplied to the substrate may be spread to each of a center side of the substrate and to an edge side of the substrate.

According to the exemplary embodiment, in the processing operation, when a location from which the treatment liquid is supplied is referred to as a first position, and a center of the distance from the center of the substrate to the edge of the substrate is referred to as a second location, the first position may be located closer to the center of the substrate than the second position.

According to the exemplary embodiment, in the processing operation, when the distance from the center of the substrate to the edge of the substrate is referred to as a first distance, the first position may be selected within a range of 5% to 15% of the first distance from the center of the substrate.

According to the exemplary embodiment, the treatment liquid may contain an ammonia component.

Still another exemplary embodiment of the present invention provides an apparatus for processing a substrate, the apparatus including: a chamber having a processing space; a support unit for supporting and rotating the substrate in the processing space; a liquid discharge unit including a nozzle for discharging a treatment liquid onto a substrate supported by the support unit in a liquid phase; a liquid supply unit for supplying the treatment liquid to the liquid discharge unit; a dissolved oxygen amount detection unit connected to the liquid discharge unit, and detecting the amount of dissolved oxygen of the treatment liquid and calculating dissolved oxygen amount data; and a controller that receives the dissolved oxygen amount data in linkage with the dissolved oxygen amount detection unit, and varies the position at which the treatment liquid is supplied according to the dissolved oxygen amount data, in which wherein when viewed from above, the nozzle is spaced apart from a center of the substrate such that when the treatment liquid is supplied to the substrate rotated by the support unit, the treatment liquid is not sprayed by the nozzle at a position overlapping the center of the substrate, the nozzle is disposed at a distance apart in an upward direction from a top surface of the substrate to supply the treatment liquid, the nozzle supplies the treatment liquid in a direction vertical to the top surface of the substrate, the nozzle discharges the treatment liquid at a location close to the center of the substrate between a distance to the center of the substrate and a distance to an edge of the substrate, the treatment liquid supplied to the substrate is spread to each of the center side of the substrate and to the edge side of the substrate, when the distance from the center of the substrate to the edge of the substrate is referred to as a first distance, the first position is selected within a range of 5% to 15% of the first distance from the center of the substrate, the treatment liquid contains an ammonia component, organic residues and particles are formed on the substrate before the treatment liquid is supplied, and the treatment liquid is formed with the amount of dissolved oxygen of 1500 ppb to 2500 ppb.

According to the present invention, it is possible to maintain the etch rate of the substrate within a predetermined range by preventing the amount of dissolved oxygen from being concentrated in a specific region of the substrate when a chemical is supplied to a center of the substrate.

The effect of the present invention is not limited to the foregoing effects, and non-mentioned effects will be clearly understood by those skilled in the art from the present specification and the accompanying drawings.

### BRIEF DESCRIPTION OF THE DRAWINGS

Various features and advantages of the non-limiting exemplary embodiments of the present specification may become apparent upon review of the detailed description in conjunction with the accompanying drawings. The attached drawings are provided for illustrative purposes only and should not be construed to limit the scope of the claims. The accompanying drawings are not considered to be drawn to scale unless explicitly stated. Various dimensions in the drawing may be exaggerated for clarity.

FIG. 1 is a top plan view schematically illustrating an interior of a substrate processing facility according to an exemplary embodiment of the present invention.

FIG. 2 is a longitudinal cross-sectional view schematically illustrating the substrate processing apparatus illustrated in FIG. 1.

FIG. 3 is a flowchart of a substrate processing method according to the present invention.

FIG. 4 is a top plan view schematically illustrating a location of a first nozzle of the substrate processing apparatus in a first processing operation illustrated in FIG. 3.

FIG. 5 is a top plan view schematically illustrating a location of a second nozzle of the substrate processing apparatus in a second processing operation illustrated in FIG. 3.

FIG. 6 is a top plan view schematically illustrating a location of a third nozzle of the substrate processing apparatus during a drying operation illustrated in FIG. 3.

FIG. 7 is a top plan view schematically illustrating a location of a first nozzle of the substrate processing apparatus in the second processing operation illustrated in FIG. 3.

FIG. 8 is a front view of the substrate processing apparatus illustrated in FIG. 7.

FIG. 9 is a graph of an etch rate from a center to an edge of the substrate illustrated in FIGS. 7 and 8.

FIG. 10 is a front view of a comparative example for comparison with the substrate processing apparatus of FIG. 8.

FIG. 11 is a graph of an etch rate from a center to an edge of the substrate illustrated in FIG. 10.

FIG. 12 is a front view of a substrate processing apparatus according to another exemplary embodiment of the present invention.

FIG. 13 is an enlarged front view of the substrate processing apparatus illustrated in FIG. 12.

FIG. 14 is a flowchart of a substrate processing method for the substrate processing apparatus illustrated in FIG. 12.

### DETAILED DESCRIPTION

Example embodiments will now be described more fully with reference to the accompanying drawings. Example embodiments are provided so that this disclosure will be thorough and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

When the term “same” or “identical” is used in the description of example embodiments, it should be understood that some imprecisions may exist. Thus, when one element or value is referred to as being the same as another element or value, it should be understood that the element or value is the same as the other element or value within a manufacturing or operational tolerance range (e.g., ±10%).

When the terms “about” or “substantially” are used in connection with a numerical value, it should be understood that the associated numerical value includes a manufacturing or operational tolerance (e.g., ±10%) around the stated numerical value. Moreover, when the words “generally” and “substantially” are used in connection with a geometric shape, it should be understood that the precision of the geometric shape is not required but that latitude for the shape is within the scope of the disclosure.

Unless otherwise defined, all terms (including technical and scientific terms) used herein have the same meaning as commonly understood by one of ordinary skill in the art to which example embodiments belong. It will be further understood that terms, including those defined in commonly used dictionaries, should be interpreted as having a meaning that is consistent with their meaning in the context of the relevant art and will not be interpreted in an idealized or overly formal sense unless expressly so defined herein.

In the present exemplary embodiment, a wafer will be described as an example of an object to be processed. However, the technical spirit of the present invention may be applied to devices used for other types of substrate processing, in addition to wafers.

Hereinafter, exemplary embodiments of the present invention will be described with reference to the accompanying drawings.

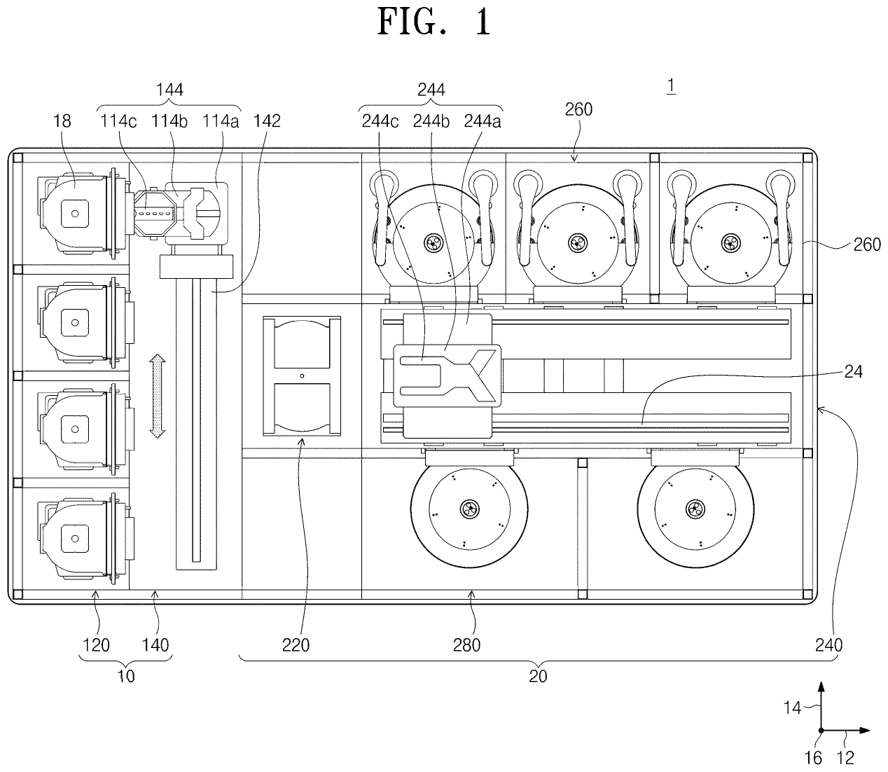

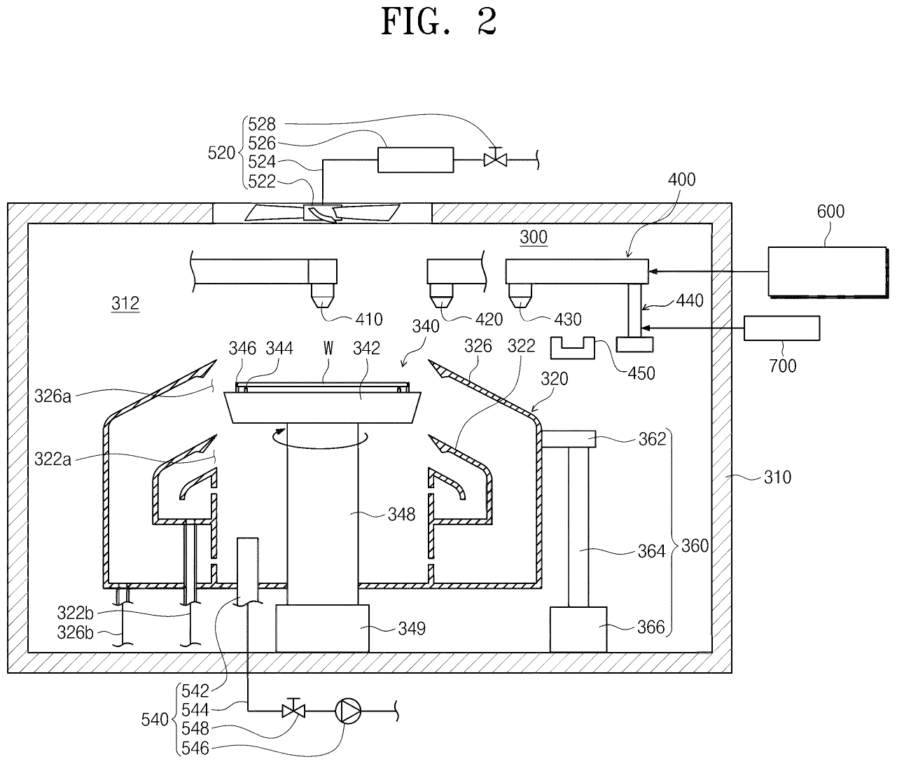

FIG. 1 is a top plan view schematically illustrating an interior of a substrate processing facility according to an exemplary embodiment of the present invention. FIG. 2 is a longitudinal cross-sectional view schematically illustrating the substrate processing apparatus illustrated in FIG. 1.

Referring to FIGS. 1 and 2, a substrate processing facility 1 includes an index module 10 and a process processing module 20, and the index module 10 includes a load port 120 and a transfer frame 140. The load port 120, the transfer frame 140, and the process processing module 20 are arranged in sequential rows. Hereinafter, a direction in which the load port 120, the transfer frame 140, and the process processing module 20 are arranged is referred to as a first direction 12, a direction perpendicular to the first direction 12 when viewed from above is referred to as a second direction 14, and a direction perpendicular to a plane including the first direction 12 and the second direction 14 is referred to as a third direction 16.

A carrier 18 in which a substrate W is accommodated is seated on the load port 120. A plurality of load ports 120 is provided and is arranged in a line along the second direction 14. In FIG. 1, it is illustrated that four load ports 120 are provided. However, the number of load ports 120 may be increased or decreased depending on conditions, such as process efficiency and footprint of the process processing module 20. Slots (not illustrated) provided to support an edge of the substrate are formed in the carrier 18. A plurality of slots is provided in the third direction 16, and the substrates are positioned within the carrier so as to be stacked while being spaced apart from each other in the third direction 16. As the carrier 18, a Front Opening Unified Pod (FOUP) may be used.

The process processing module 20 may include a buffer unit 20, a transfer chamber 240, and process chambers 260 and 280. The transfer chamber 240 is disposed so that a longitudinal direction thereof is parallel to the first direction 12. The process chambers 260 and 280 are disposed on opposite sides of the transfer chamber 240 in the second direction 14. The process chambers 260 may be provided to be symmetrical to each other relative to the transfer chamber 240. Some of the process chambers 260 and 280 are disposed along the longitudinal direction of the transfer chamber 240. Additionally, some of the process chambers 260 and 280 are arranged to be stacked on top of each other. That is, the process chambers 240 may be disposed in an array of A×B (A and B are natural numbers equal to or greater than 1) on opposite sides of the transfer chamber 240. Here, A is the number of process chambers 260 and 280 provided in a line along the first direction 12, and B is the number of process chambers 260 and 280 provided in a line along the third direction 16. When four or six process chambers 260 are provided on each of the opposite sides of the transfer chamber 240, the process chambers 260 and 280 may be disposed in an array of 2×2 or 3×2. The number of process chambers 260 and 280 may be increased or decreased. Unlike the foregoing, the process chamber 260 may be provided only to one side of the transfer chamber 240. In addition, the process chambers 260 and 280 may be provided as a single layer on one side and the opposite sides of the transfer chamber 240. In addition, the process chambers 260 and 280 may be provided in various arrangements unlike the above.

The process chambers 260 and 280 of the present exemplary embodiment may be categorized as including a cleaning chamber and a drying chamber. In this case, the cleaning chamber may be a substrate processing apparatus for cleaning the substrate, which will be described below, and the drying chamber may be a substrate processing apparatus for drying the substrate.

The buffer unit 220 is disposed between the transfer frame 140 and the transfer chamber 240. The buffer unit 220 may provide a space in which the substrate W stays before the substrate W is transferred between the transfer chamber 240 and the transfer frame 140. The buffer unit 220 is provided with slots (not illustrated) on which the substrate W is placed therein, and the slots (not illustrated) are provided in plurality so as to be spaced apart from each other in the third direction 16. In the buffer unit 220, a side facing the transfer frame 140 and a side facing the transfer chamber 240 are each open.

The transfer frame 140 transfers the substrate W between the carrier 18 seated at the load port 120 and the buffer unit 220. The transfer frame 140 is provided with an index rail 142 and an index robot 144. The index rail 142 is provided so that a longitudinal direction thereof is parallel to the second direction 14. The index robot 144 is installed on the index rail 142, and linearly moves in the second direction 14 along the index rail 142. The index robot 144 includes a base 144a, a body 144b, and an index arm 144c. The base 144a is installed to be movable along the index rail 142. The body 144b is coupled to the base 144a. The body 144b is provided to be movable in the third direction 16 on the base 144a. Further, the body 144b is provided to be rotatable on the base 144a. The index arm 144c is coupled to the body 144b and is provided to be movable forwardly and backwardly with respect to the body 144b. A plurality of index arms 144c is provided to be individually driven. The index arms 144c are disposed to be stacked in the state of being spaced apart from each other in the third direction 16. Some of the index arms 144c may be used when the substrate W is transferred from the process processing module 20 to the carrier 18, and another some of the plurality of index arms 144c may be used when the substrate W is transferred from the carrier 130 to the process processing module 20. This may prevent the particles generated from the substrate W before the process processing from being attached to the substrate W after the process processing in the process in which the index robot 144 loads and unloads the substrate W.

The transfer chamber 240 transfers the substrate W between the buffer unit 220 and the process chambers 260. A guide rail 242 and a main robot 244 are provided to the transfer chamber 240. The guide rail 242 is disposed so that a longitudinal direction thereof is parallel to the first direction 12. The main robot 244 is installed on the guide rail 242 and linearly moved along the first direction 12 on the guide rail 242. The main robot 244 includes a base 244a, a body 244b, and a main arm 244c. The base 244a is installed to be movable along the guide rail 242. The body 244b is coupled to the base 244a. The body 244b is provided to be movable in the third direction 16 on the base 244a. Further, the body 244b is provided to be rotatable on the base 244a. The main arm 244c is coupled to the body 244b, and provided to be movable forwardly and backwardly with respect to the body 244b.

Further, the process chamber 260 is provided with a substrate processing apparatus 300. In the present exemplary embodiment, the case where the substrate processing apparatus 300 performs a liquid treatment process on the substrate will be described as an example. The liquid treatment process may further include a process of cleaning the substrate.

In one example, the substrate processing apparatus 300 includes a chamber 310, a processing container 320, a spin head 340, a lifting unit 360, a liquid discharge unit 400, an airflow forming unit 500, a liquid supply unit 600, and a controller 700.

The chamber 310 provides a processing space 312 within which a process for processing the substrate W is performed.

The processing container 320 is positioned in the processing space 312 and is provided in the shape of a cup with an open top. When viewed from above, the processing container 320 is positioned to overlap an exhaust pipe. The processing container 320 includes an internal collection container 322 and an external collection container 326. Each of the collection containers 322 and 326 collects a different treatment liquid from the treatment liquids used in the process. The internal collection container 322 is provided in the shape of an annular ring surrounding the spin head 340, and the external collection container 326 is provided in the shape of an annular ring surrounding the internal collection container 322. An inner space 322a of the internal collection container 322 and a space 326a between the external collection container 326 and the internal collection container 322 function as inlets for the treatment liquid to flow into the internal collection container 322 and the external collection container 326, respectively. Collection lines 322b and 326b are connected to the bottom surfaces of the collection containers 322 and 326, respectively, to extend vertically in the down direction. Each of the collection lines 322b and 326b functions as a discharge pipe to discharge the treatment liquid that has been introduced through the respective collection containers 322 and 326. The discharged treatment liquid may be reused through an external treatment liquid regeneration system (not illustrated).

The spin head 340 is provided as a support unit for supporting and rotating the substrate W. The spin head 340 is disposed within the processing container 320. The spin head 340 supports the substrate W and rotates the substrate W during the process. The spin head 340 includes a chuck body 342, a support pin 344, a chuck pin 346, and a support shaft 348. The chuck body 342 has a top surface that is provided in a substantially circular shape when viewed from above. The support shaft 348 rotatable by a motor 349 is fixedly coupled to the bottom surface of the chuck body 342. A plurality of support pins 344 is provided. The support pins 344 are disposed to be spaced apart at predetermined intervals on the edge of the upper surface of the chuck body 342 and protrude upwardly from the chuck body 342. The support pins 334 are arranged in combination with each other to have an overall annular ring shape. The support pin 344 supports an edge of the rear surface of the substrate W so that the substrate W is spaced apart from the upper surface of the spin chuck 342 at a predetermined distance. A plurality of chuck pins 346 is provided. The chuck pin 346 is disposed to be farther from the center of the chuck body 342 than the support pin 344. The chuck pin 346 is provided to protrude upwardly from the chuck body 342. The chuck pin 346 supports a side portion of the substrate W such that the substrate W does not move laterally from a regular position when the spin head 340 is rotated. The chuck pin 346 is provided to move linearly between the standby position and the support position along the radial direction of the chuck body 342. The standby position is a position farther from the center of the chuck body 342 relative to the support position. When the substrate W is loaded to or unloaded from the spin head 340, the chuck pin 346 is positioned in the standby position, and when the process is performed on the substrate W, the chuck pin 346 is positioned in the support position. In the support position, the chuck pin 346 is in contact with the side portion of the substrate W.

The lifting unit 360 adjusts the relative height between the processing container 320 and the spin head 340. The lifting unit 360 linearly moves the processing container 320 in the vertical direction. As the processing container 320 moves in the vertical direction, the relative height of the processing container 320 with respect to the spin head 340 changes. The lifting unit 460 includes a bracket 360, a moving shaft 362, and a driver 364. The bracket 362 is fixedly installed on the outer wall of the processing container 320, and a moving shaft 364, which is moved in the vertical direction by a driver 366, is fixedly coupled to the bracket 364. The processing container 320 is lowered so that the spin head 340 protrudes over the top of the processing container 320 when the substrate W is placed on or lifted from the spin head 340. In addition, when the process is in progress, the height of the processing container 320 is adjusted so that the treatment liquid is introduced into the predetermined collection container 326 according to the type of the treatment liquid supplied to the substrate W.

Unlike the description above, the lifting unit 360 may move the spin head 340 in the vertical direction instead of the processing container 320.

The liquid discharge unit 400 supplies various types of treatment liquids to the substrate W. The liquid discharge unit 400 further includes a plurality of nozzles 410 to 430. Each nozzle is coupled to a nozzle position driver 440 and is moved to the process position and the standby position by the nozzle position driver 440. The process position is defined herein as a position where the nozzles 410 to 430 are capable of discharging the treatment liquid onto the substrate W positioned within the processing container 320, and the standby position is defined as a position where the nozzles 410 to 430 are waiting outside of the process position. In one example, the process position may be a position where the nozzles 410 to 430 are capable of supplying the treatment liquid to the center C1 of the substrate W. For example, when viewed from above, the nozzles 410 to 430 may be moved linearly or axially to be moved between the process position and the standby position. The treatment liquid discharged from the liquid discharge unit 400 onto the substrate W may be a liquefied treatment liquid. Additionally, in the standby position, a collection pipe 450 may be disposed below the third nozzle 430. The collection pipe 450 collects the treatment liquid when the third nozzle 430 discharges the treatment liquid for cleaning. Additionally, the liquid discharge unit 400 may expose the treatment liquid by means of a pump.

The plurality of nozzles 410 to 430 discharges different types of liquid. The treatment fluid discharged from the nozzles 410 to 430 may include at least one of a chemical, a rinse solution, and a drying fluid. Referring to the exemplary embodiment of FIG. 2, a first nozzle 410 may be a nozzle for discharging chemicals. A second nozzle 420 may be a nozzle that discharges a rinse solution. A third nozzle 430 may be a nozzle that discharges a drying fluid. For example, the chemical may be a treatment liquid capable of etching the film formed on the substrate W or removing particles remaining on the substrate W. The chemical may be a liquid having a property of strong acid or strong base. The chemical may include sulfuric acid, hydrofluoric acid, or ammonia. The rinse solution may be a treatment liquid capable of rinsing off chemicals remaining on the substrate W. For example, the rinse solution may be pure water. The drying fluid may be provided as a treatment liquid to displace the residual rinse solution on the substrate W. The drying fluid may be a treatment liquid having low surface tension compared to the rinse liquid. The drying fluid may be an organic solvent. The drying fluid may be isopropyl alcohol (IPA). The third nozzle 430 may be connected to the liquid supply unit 600 to be described later.

The airflow forming unit 500 forms a downward airflow in the processing space 312. The airflow forming unit 500 supplies airflow from an upper portion of the chamber 310 and exhausts airflow from a lower portion of the chamber 310. The airflow forming unit 500 further includes an airflow supply unit 520 and an exhaust unit 540. The airflow supply unit 520 and the exhaust unit 540 are positioned facing each other in the vertical direction.

The airflow supply unit 520 supplies gas in the downward direction. The gas supplied from the airflow supply unit 520 may be air from which impurities are removed. The airflow supply unit 520 further includes a fan 522, an airflow supply line 524, a supply valve 528, and a filter 526. The fan 522 is installed on the ceiling surface of the chamber 310. When viewed from above, the fan 522 is positioned to face the processing container. The fan 522 may be positioned to provide air toward the substrate W positioned within the processing container. The airflow supply line 524 is connected to the fan 522 to supply air to the fan 522. A supply valve 528 is installed in the airflow supply line 524 to regulate the amount of airflow supplied. The filter 526 is installed in the airflow supply line 524 to filter the air. For example, the filter 526 may remove particles and moisture contained in the air.

The exhaust unit 540 exhausts the processing space 312. The exhaust unit 540 further includes an exhaust pipe 542, a pressure reducing member 546, and an exhaust valve 548. The exhaust pipe 542 is installed on the bottom surface of the chamber 310 and is provided as a pipe to exhaust the processing space 312. The exhaust pipe 542 is positioned such that the exhaust port faces upwardly. The exhaust pipe 542 is positioned such that the exhaust port is in communication with the interior of the processing container. That is, the top of the exhaust pipe 542 is located within the processing container. Accordingly, the downward airflow formed within the processing container is exhausted through the exhaust pipe 542.

The pressure reducing member 546 reduces pressure of the exhaust pipe 542. A negative pressure is formed in the exhaust pipe 542 by the pressure reducing member 546, which exhausts the processing container. The exhaust valve 548 is installed in the exhaust pipe 542 and opens and closes the exhaust port of the exhaust pipe 542. The exhaust valve 548 regulates the exhaust volume.

The liquid supply unit 600 supplies the treatment liquid to at least one of the plurality of nozzles 410 to 430. The liquid supply unit 600 may heat the treatment liquid. Additionally, the liquid supply unit 600 may store the treatment liquid.

The controller 700 may include a centralized computing unit. Further, the controller 700 controls the spin head 340, the lifting unit 360, the liquid discharge unit 400, the airflow forming unit 500, and the liquid supply unit 600 according to an internally preset algorithm to process the substrate W according to the recipe.

Hereinafter, a substrate processing method of the substrate processing apparatus according to an exemplary embodiment of the present invention will be described.

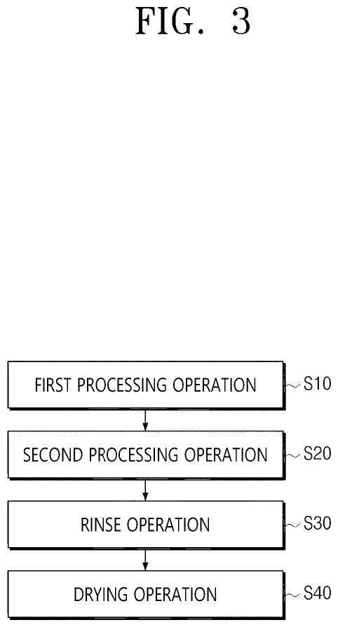

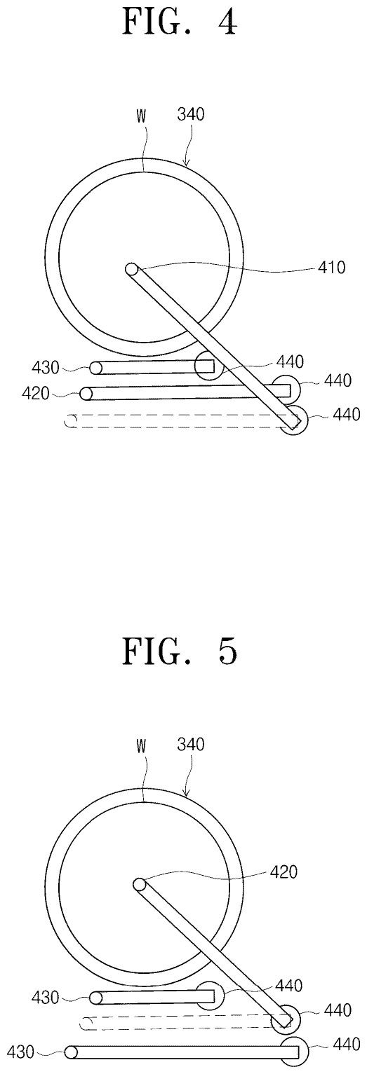

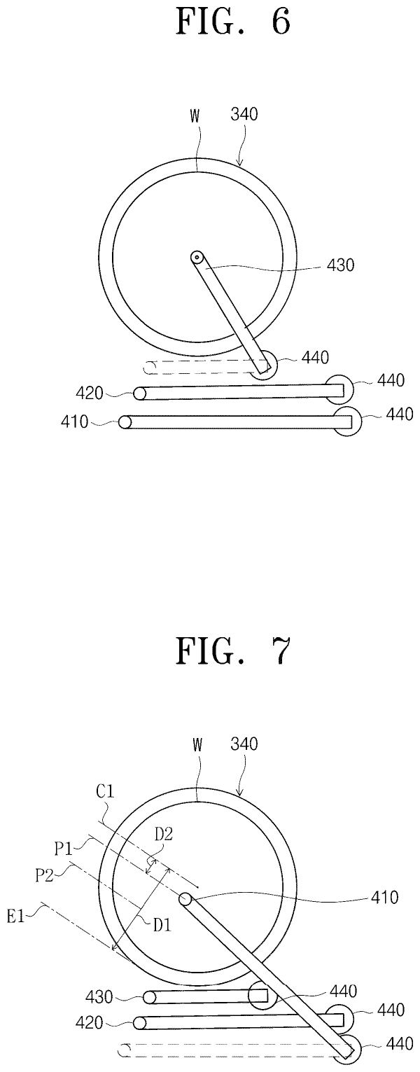

FIG. 3 is a flowchart of a substrate processing method according to the present invention. FIG. 4 is a top plan view schematically illustrating a location of a first nozzle of the substrate processing apparatus in a first processing operation illustrated in FIG. 3. FIG. 5 is a top plan view schematically illustrating a location of a second nozzle of the substrate processing apparatus in a second processing operation illustrated in FIG. 3. FIG. 6 is a top plan view schematically illustrating a location of a third nozzle of the substrate processing apparatus during a drying operation illustrated in FIG. 3.

Referring further to FIGS. 3 to 6, a substrate processing method of the substrate processing apparatus according to the present invention may include a first processing operation S10, a second processing operation S20, a rinse operation S30, and a drying operation S40.

First, in the first processing operation S10, the substrate W is rotated by rotation of the spin head 340 in the state where the substrate W is seated on to the spin head 340. Also, in the first processing operation S10, the nozzle position driver 440 is driven to move the first nozzle 410 to the area above the center C1 of the rotating substrate W, and the treatment liquid is sprayed from the first nozzle 410. In this case, the treatment liquid sprayed from the first nozzle 410 may be an acidic treatment liquid including sulfuric acid or hydrofluoric acid. Thus, in the first processing operation S10, metal residues remaining on the substrate W may be removed.

Next, in the second processing operation S20, a different treatment liquid is supplied to the substrate W rotated by the spin head 340. In this case, the treatment liquid supplied in the second processing operation S20 may be a treatment liquid containing ammonia. Thus, in the second processing operation S20, particles or organic residues remaining on the substrate W may be removed.

Next, in the rinse operation S30, the nozzle position driver 440 is driven to return the first nozzle 410 to the standby position and move the second nozzle 420 to the center C1 of the substrate W. Then, in the rinse operation S30, the second nozzle 420 supplies another treatment liquid onto the substrate W rotated by the spin head 340. In this case, the treatment liquid supplied in the rinse operation S30 may be a treatment liquid containing pure water. Thus, acidic and alkaline treatment liquids remaining on the substrate W may be removed in the rinse operation S30.

Next, in the drying operation S40, the nozzle position driver 440 is driven to return the second nozzle 420 to the standby position and move the third nozzle 430 to the area above the center C1 of the substrate W. Then, in the rinse operation S30, the drying fluid is supplied onto the substrate W rotated by the spin head 340. In this case, the drying fluid supplied in the drying operation S40 may be isopropyl alcohol (IPA). Therefore, in the drying operation S40, the substrate W may be dried in a state in which the stains remaining on the substrate W are removed by the first processing operation S10, the second processing operation S20, and the rinse operation S30.

Hereinafter, an exemplary embodiment of the second processing operation S20 will be described in more detail.

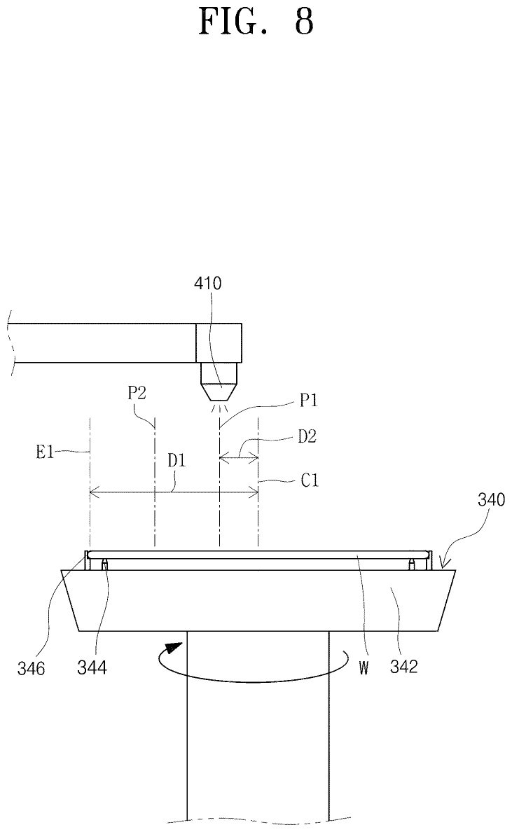

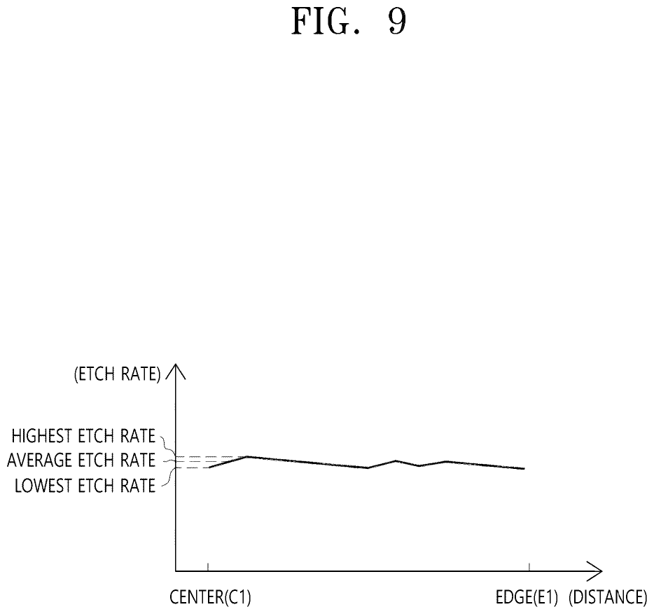

FIG. 7 is a top plan view schematically illustrating a location of the first nozzle of the substrate processing apparatus in the second processing operation illustrated in FIG. 3. FIG. 8 is a front view of the substrate processing apparatus illustrated in FIG. 7. FIG. 9 is a graph of an etch rate from a center to an edge of the substrate illustrated in FIGS. 7 and 8.

As illustrated in FIGS. 7 to 9, in the second processing operation S20, another treatment liquid is supplied from the first nozzle 410 onto the substrate W rotated by the spin head 340. Here, organic residues and particles are formed on the substrate W. In this case, the first nozzle 410 may spray the treatment liquid in a state where the first nozzle 410 is disposed at a certain distance from above surface of the substrate W in an upward direction. In this case, the first nozzle 410 may supply the treatment liquid in a direction perpendicular to the top surface of the substrate W so that the treatment liquid is not biased in any one direction.

Additionally, the treatment liquid supplied from the first nozzle 410 may be formed of a component containing ammonia. For example, the treatment liquid may be formed as a solution of SC-1 (H2O2+NH4OH). Further, the treatment liquid may be formed with a dissolved oxygen content of 1500 ppb to 2500 ppb. Here, the treatment liquid may have a dissolved oxygen content lower than 1500 ppb or higher than 2500 ppb, which may cause the overall etch rate to be too low or too high.

Furthermore, in the second processing operation S20, the spray center of the first nozzle 410 is not disposed in the upper space of the center C1 of the substrate W, but the treatment liquid may be supplied at a first position P1 spaced apart from the center C1 of the substrate W. In other words, the spray center of the first nozzle 410 is disposed so as not to overlap the center C1 of the substrate W. Here, the first position P1 is a position spaced apart from the center C1 of the substrate W, and may be positioned to be close to the center C1 of the substrate W in the distance to the center C1 of the substrate W and the distance from the edge E1 of the substrate W. For example, when it is assumed that a distance of the first nozzle 410 spaced from the center C1 of the substrate W is D2, and the distance from the center C1 of the substrate W to the edge E1 of the substrate W is a first distance D1, the first position P1 may be located within a range of 4% to 20% of the first distance D1. Therefore, the treatment liquid supplied at a distance from the center C1 of the substrate W within the above range may prevent the amount of dissolved oxygen from being concentrated near the center C1 of the substrate W. Here, in the case where the range is less than 4% of the first distance D1, the treatment liquid is concentrated on the center C1 of the substrate W to increase the amount of dissolved oxygen, so that the etch rate for the center C1 of the substrate W may be significantly higher than the average etch rate. Furthermore, in the case where the range is greater than 20% of the first distance D1, the amount of dissolved oxygen in the treatment liquid toward the edge E1 of the substrate W may become so low that the etch rate near the edge E1 may become significantly lower than the average etch rate.

Also, when it is assumed that the center of the distance from the center C1 of the substrate W to the edge E1 of the substrate W is referred to as a second position P2, the first position P1 is located closer to the center of the substrate W than the second position P2 of the substrate W, so that the amount of dissolved oxygen may be prevented from being concentrated near the center C1 of the substrate. Thus, the amount of dissolved oxygen is not concentrated in the center C1 of the substrate W and the amount of dissolved oxygen near the edge E1 becomes too low, so that the etch rate to the center C1 of the substrate W and the etch rate to the edge E1 of the substrate W may be formed to be similar to the average etch rate.

Further, when the first nozzle 410 is located at the first position P1 and supplies another treatment liquid to the substrate W rotated by the spin head 340, the treatment liquid is spread from the first position P1 to the center C1 side of the substrate W by the centrifugal force of the rotating substrate W, and is spread from the first position P1 to the edge E1 side of the substrate W by the centrifugal force. Thus, the treatment liquid may spread to the center C1 side of the substrate W and the edge E1 side of the substrate W, respectively, so that the amount of dissolved oxygen is not concentrated in any one place. Furthermore, the treatment liquid spread to the edge E1 of the substrate W is quickly discharged as it passes the edge E1 of the substrate W and falls at an angle into the space 326a of the collection container 322. Therefore, since the flow rate of the treatment liquid near the edge E1 of the substrate W is greatly increased compared to the center, the substrate W may be quickly discharged as it goes toward the edge E1, resulting in a relatively lower etch rate than the center. However, when the treatment liquid is supplied from the first position P1 rather than the center C1 of the substrate W, the treatment liquid travels a shorter distance to the edge E1 of the substrate, so that the etch rate near the edge E1 is not significantly reduced from the average value.

In this way, the substrate processing apparatus and the substrate processing method of the present invention are capable of etching the substrate W with the highest etch rate and the lowest etch rate of the substrate W which are close to the average etch rate within a certain range, as illustrated in FIG. 9.

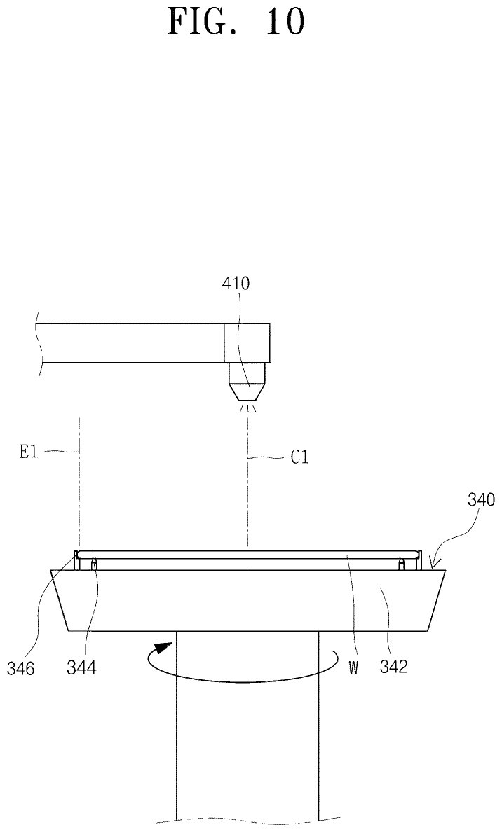

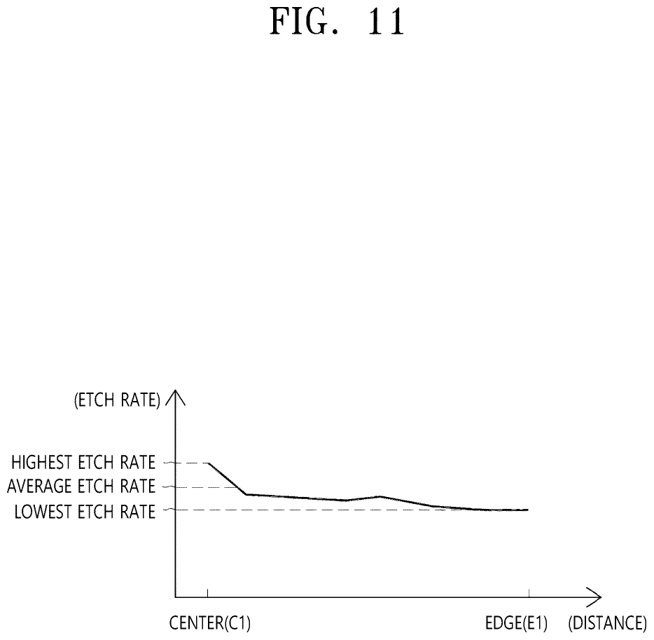

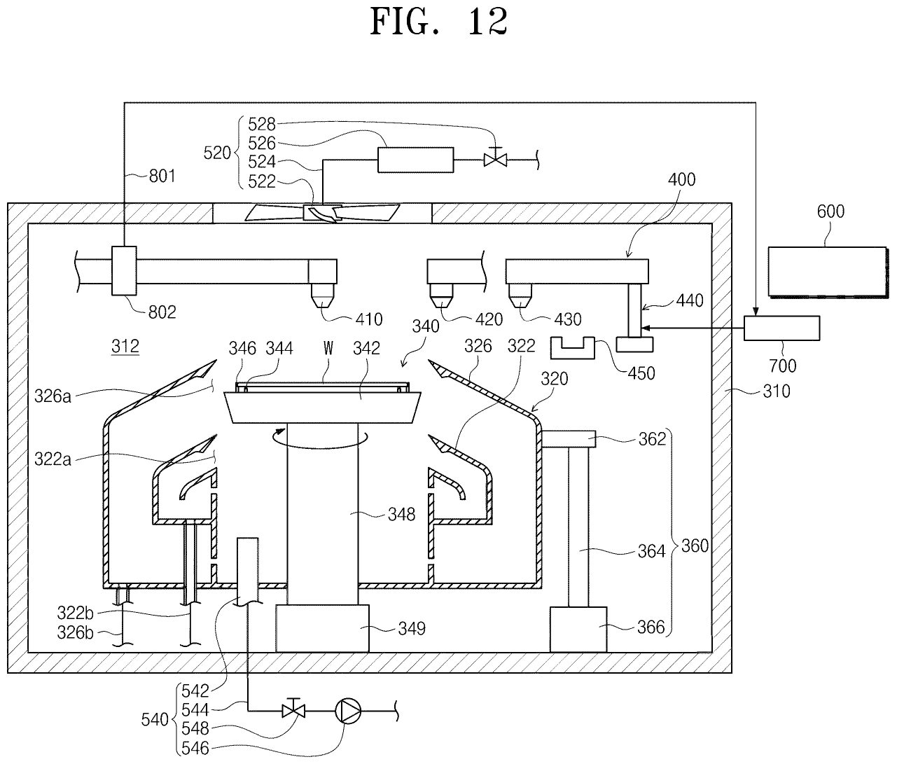

FIG. 10 is a front view of a comparative example for comparison with the substrate processing apparatus of FIG. 8. FIG. 11 is a graph of an etch rate from a center to an edge of the substrate illustrated in FIG. 10.

As illustrated in FIG. 10, a substrate processing apparatus according to a comparative example supplies another treatment liquid onto the substrate W rotated by the spin head 340 in the state where the first nozzle 410 is positioned at the center C1 of the substrate W. In this case, the treatment liquid supplied to the center C1 of the substrate W spreads from the center C1 to the vicinity of the edge E1 of the substrate W.

In this case, as illustrated in FIG. 11, in the substrate processing apparatus according to the comparative example, the amount of dissolved oxygen is concentrated near the center C1 of the substrate W, so that the highest etch rate is much greater than the average etch rate. Also, since the amount of dissolved oxygen becomes too low near the edge E1 of the substrate W, the lowest etch rate is formed much lower than the average etch rate. Thus, the substrate W is etched unevenly over the entire area.

However, unlike the comparative example, the substrate processing apparatus of the foregoing exemplary embodiment is capable of uniformly etching the entire surface of the substrate W because the highest etch rates and the lowest etch rates near the center C1 and the edge E1 of the substrate W are close to the average etch rates, as illustrated in FIG. 9.

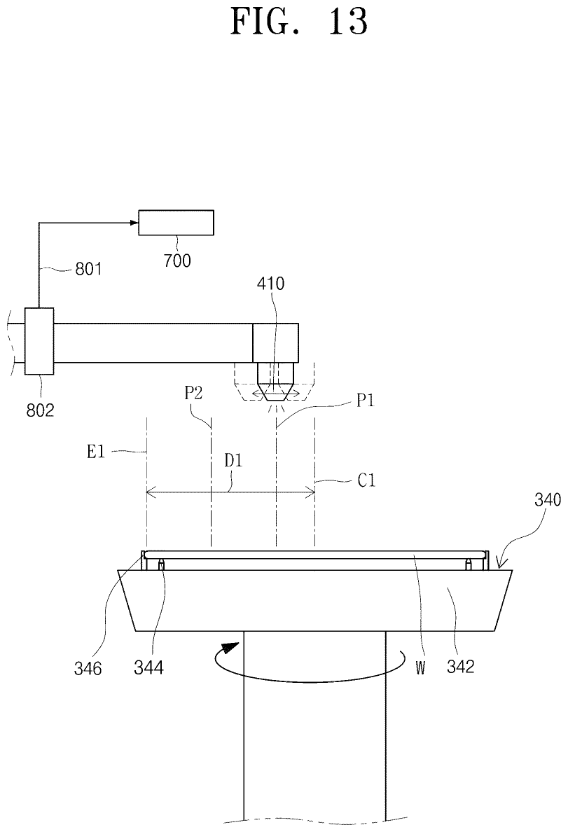

FIG. 12 is a front view of a substrate processing apparatus according to another exemplary embodiment of the present invention. FIG. 13 is an enlarged front view of the substrate processing apparatus illustrated in FIG. 12.

As illustrated in FIG. 12, a substrate processing apparatus according to another exemplary embodiment of the present invention includes a chamber 310, a processing container 320, a spin head 340, a lifting unit 360, a liquid discharge unit 400, an airflow forming unit 500, a liquid supply unit 600, and a controller 700. Here, the liquid supply unit 600 may further include a signal line 801 and a dissolved oxygen amount detection unit 802.

In the present exemplary embodiment, the chamber 310, the processing container 320, the spin head 340, the lifting unit 360, the liquid discharge unit 400, and the airflow forming unit 500 are the same as those of the substrate processing apparatus 300 described above, so a redundant description thereof will be omitted.

In the present exemplary embodiment, the controller 700, the signal line 801, and the dissolved oxygen amount detection unit 802 will be mainly described.

The signal line 801 electrically connects the dissolved oxygen detection unit 802 and the controller 700. The signal line 801 transmits dissolved oxygen amount data detected by the dissolved oxygen amount detection unit 802 to the controller 700.

The dissolved oxygen amount detection unit 802 continuously detects the dissolved oxygen amount in the treatment liquid supplied to the first nozzle 410 and calculates the dissolved oxygen amount data of the discharged treatment liquid. In this case, the calculated dissolved oxygen data is transmitted to the controller 700.

The controller 700 controls the spin head 340, the lifting unit 360, the liquid discharge unit 400, the airflow forming unit 500, and the liquid supply unit 600 according to an internally set algorithm, as described above. Further, the controller 700 is interfaced with the dissolved oxygen amount detection unit 802 and receives the dissolved oxygen amount data from the dissolved oxygen amount detection unit 802. The controller 700 performs control to change the position of the first nozzle 410 by driving the nozzle position driver 440 according to the data of the dissolved oxygen amount in the treatment liquid discharged from the first nozzle 410. For example, when the amount of dissolved oxygen in the treatment liquid is too low, the position of the first nozzle 410 may be moved a certain distance from the first position P1 that is the reference position to face the center C1 of the substrate W, or when the amount of dissolved oxygen is too high, the position of the first nozzle 410 may be moved from the first position P1 that is the reference position to face the edge E1 of the substrate W. In this way, the substrate processing apparatus according to another exemplary embodiment of the present invention may maintain the etch rate at a constant range level in the event that the amount of dissolved oxygen in the treatment liquid is too high or too low and the etch rate changes.

Here, a first position P1 of the first nozzle 410 is a position spaced apart from the center C1 of the substrate W, and may be positioned to be close to the center C1 of the substrate W in the distance to the center C1 of the substrate W and the distance from the edge E1 of the substrate W. In this case, when it is assumed that the distance from the center C1 of the substrate W to the edge E1 of the substrate W is a first distance D1, the first position P1 may be located within a range of 4% to 20% of the first distance D1. Also, when it is assumed that the center of the distance from the center C1 of the substrate W to the edge E1 of the substrate W is referred to as a second position P2, the first position P1 may be located closer to the center of the substrate W than the second position P2.

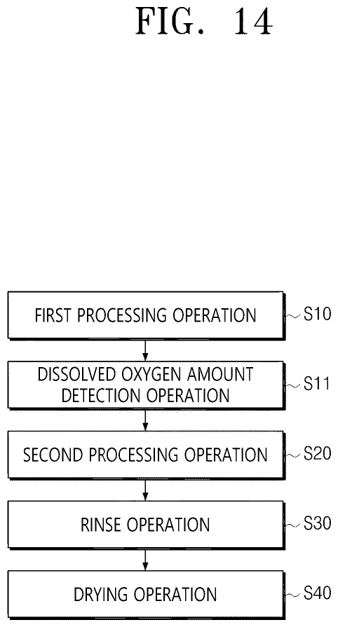

FIG. 14 is a flowchart of a substrate processing method for the substrate processing apparatus illustrated in FIG. 12.

Referring further to FIG. 14, another substrate treatment method of the present invention may include a first processing operation S10, a dissolved oxygen amount detection operation S11, a second processing operation S20, a rinse operation S30, and a drying operation S40.

Here, the first processing operation S10, the rinse operation S30, and the drying operation S40 are the same as those in the preceding exemplary embodiment, and therefore, a redundant description will be omitted.

In the dissolved oxygen amount detection operation S11, the dissolved oxygen amount detection unit 802 continuously detects the dissolved oxygen amount in the treatment liquid, calculates the dissolved oxygen amount data, and transmits the dissolved oxygen amount data to the controller 700.

In the second treatment operation S20, the treatment liquid is supplied from the first position P1 identically to the second treatment operation S20 described above. Also, in the second treatment operation S20, the controller 700 drives the nozzle position driver 440 according to the data of the amount of dissolved oxygen in the treatment liquid discharged from the first nozzle 410, as described above. In this case, in the second treatment operation S20, when the amount of dissolved oxygen in the treatment liquid is too low, the controller 700 controls the position of the first nozzle 410 to move a certain distance from the first position P1, which is a reference position, toward the center C1 of the substrate W. Furthermore, in the second treatment operation S20, when the amount of dissolved oxygen is too high, the controller 700 controls the position of the first nozzle 410 to face the edge E1 of the substrate W from the first position P1, which is the reference position. In this case, the controller 700 may control the position of the first nozzle 410 such that the distance traveled by the first nozzle 410 is proportional or inversely proportional to the dissolved oxygen amount data. Thus, the substrate processing method according to another exemplary embodiment of the present invention may maintain the etch rate at a constant range level when the amount of dissolved oxygen in the treatment liquid is too high or too low to cause a change in the etch rate.

It should be understood that exemplary embodiments are disclosed herein and that other variations may be possible. Individual elements or features of a particular exemplary embodiment are not generally limited to the particular exemplary embodiment, but are interchangeable and may be used in selected exemplary embodiments, where applicable, even if not specifically illustrated or described. The modifications are not to be considered as departing from the spirit and scope of the disclosure, and all such modifications that would be obvious to one of ordinary skill in the art are intended to be included within the scope of the accompanying claims.

What is claimed is:

1. An apparatus for processing a substrate, the apparatus comprising:
a chamber having a processing space;
a support unit for supporting and rotating a substrate in the processing space;
a liquid discharge unit including a nozzle for discharging a treatment liquid onto a substrate supported by the support unit in a liquid phase; and
a liquid supply unit for supplying the treatment liquid to the liquid discharge unit,
wherein, when viewed from above, the nozzle is spaced apart from a center of the substrate such that when the treatment liquid is supplied to the substrate rotated by the support unit, the treatment liquid is not sprayed by the nozzle at a position overlapping the center of the substrate.

2. The apparatus of claim 1, wherein the nozzle is disposed at a predetermined distance apart in an upward direction from a top surface of the substrate to supply the treatment liquid.

3. The apparatus of claim 2, wherein the nozzle supplies the treatment liquid in a direction vertical to the top surface of the substrate.

4. The apparatus of claim 1, wherein the nozzle discharges the treatment liquid at a location close to the center of the substrate between a distance to the center of the substrate and a distance to an edge of the substrate.

5. The apparatus of claim 4, wherein the treatment liquid supplied to the substrate is spread to each of a center side of the substrate and to an edge side of the substrate.

6. The apparatus of claim 5, wherein when a location from which the treatment liquid is supplied is referred to as a first position, and a center of the distance from the center of the substrate to the edge of the substrate is referred to as a second location, the first position is located closer to the center of the substrate than the second position.

7. The apparatus of claim 6, wherein when the distance from the center of the substrate to the edge of the substrate is referred to as a first distance, the first position is selected within a range of 5% to 15% of the first distance from the center of the substrate.

8. The apparatus of claim 1, wherein the treatment liquid contains an ammonia component.

9. The apparatus of claim 1, wherein organic residues and particles are formed on the substrate before the treatment liquid is supplied.

10. The apparatus of claim 1, wherein the treatment liquid is formed with the amount of dissolved oxygen of 1500 ppb to 2500 ppb.

11. The apparatus of claim 1, further comprising:
a dissolved oxygen amount detection unit that is connected to the liquid discharge unit, and detects the amount of dissolved oxygen of the treatment liquid and calculates dissolved oxygen amount data; and
a controller that receives the dissolved oxygen amount data in linkage with the dissolved oxygen amount detection unit, and varies a position at which the treatment liquid is supplied according to the dissolved oxygen amount data.

12. A substrate processing method of processing a substrate, the substrate processing method comprising:
a processing operation of supplying a treatment liquid through a nozzle onto a substrate rotating while being seated on a support unit; and
a rinse operation of supplying another treatment liquid through a nozzle onto the substrate rotating while being seated on the support unit to remove the treatment liquid,
wherein in the processing operation, when viewed from above, the nozzle is spaced apart from a center of the substrate such that when the treatment liquid is supplied to the substrate rotated by the support unit, the treatment liquid is not sprayed at a position overlapping the center of the substrate.

13. The substrate processing method of claim 12, wherein in the processing operation, the nozzle is disposed at a predetermined distance apart in an upward direction from a top surface of the substrate to supply the treatment liquid.

14. The substrate processing method of claim 12, wherein in the processing operation, the nozzle supplies the treatment liquid in a direction vertical to the top surface of the substrate.

15. The substrate processing method of claim 12, wherein in the processing operation, the nozzle discharges the treatment liquid at a location close to the center of the substrate between a distance to the center of the substrate and a distance to an edge of the substrate.

16. The substrate processing method of claim 15, wherein in the processing operation, the treatment liquid supplied to the substrate is spread to each of a center side of the substrate and to an edge side of the substrate.

17. The substrate processing method of claim 16, wherein in the processing operation, when a location from which the treatment liquid is supplied is referred to as a first position, and a center of the distance from the center of the substrate to the edge of the substrate is referred to as a second location, the first position is located closer to the center of the substrate than the second position.

18. The substrate processing method of claim 17, wherein in the processing operation, when the distance from the center of the substrate to the edge of the substrate is referred to as a first distance, the first position is selected within a range of 5% to 15% of the first distance from the center of the substrate.

19. The substrate processing method of claim 12, wherein the treatment liquid contains an ammonia component.

20. An apparatus for processing a substrate, the apparatus comprising:
a chamber having a processing space;
a support unit for supporting and rotating the substrate in the processing space;
a liquid discharge unit including a nozzle for discharging a treatment liquid onto a substrate supported by the support unit in a liquid phase;
a liquid supply unit for supplying the treatment liquid to the liquid discharge unit;
a dissolved oxygen amount detection unit connected to the liquid discharge unit, and detecting the amount of dissolved oxygen of the treatment liquid and calculating dissolved oxygen amount data; and
a controller that receives the dissolved oxygen amount data in linkage with the dissolved oxygen amount detection unit, and varies the position at which the treatment liquid is supplied according to the dissolved oxygen amount data,
wherein, when viewed from above, the nozzle is spaced apart from a center of the substrate such that when the treatment liquid is supplied to the substrate rotated by the support unit, the treatment liquid is not sprayed by the nozzle at a position overlapping the center of the substrate, the nozzle is disposed at a predetermined distance apart in an upward direction from a top surface of the substrate to supply the treatment liquid, the nozzle supplies the treatment liquid in a direction vertical to the top surface of the substrate, the nozzle discharges the treatment liquid at a location close to the center of the substrate between a distance to the center of the substrate and a distance to an edge of the substrate, the treatment liquid supplied to the substrate is spread to each of a center side of the substrate and to an edge side of the substrate, when a location from which the treatment liquid is supplied is referred to as a first position, and a center of the distance from the center of the substrate to the edge of the substrate is referred to as a second location, the first position is located closer to the center of the substrate than the second position, when the distance from the center of the substrate to the edge of the substrate is referred to as a first distance, the first position is selected within a range of 5% to 15% of the first distance from the center of the substrate, the treatment liquid contains an ammonia component, organic residues and particles are formed on the substrate before the treatment liquid is supplied, and the treatment liquid is formed with the amount of dissolved oxygen of 1500 ppb to 2500 ppb.
